(19) United States
(12) Patent Application Publication
(10) Pub. No.: US 2015/0155356 A1
(43) Pub. Date: Jun. 4, 2015

(54) SEMICONDUCTOR LAMINATE STRUCTURE AND SEMICONDUCTOR ELEMENT

(71) Applicants: TAMURA CORPORATION, Tokyo (JP); KOHA CO., LTD., Tokyo (JP)

(72) Inventors: Kazuyuki Iizuka, Tokyo (JP); Shinya Watanabe, Tokyo (JP); Kimiyoshi Koshi, Tokyo (JP); Daiki Wakimoto, Tokyo (JP); Yoshihiro Yamashita, Tokyo (JP); Shinkuro Sato, Tokyo (JP)

(73) Assignees: TAMURA CORPORATIO9N, Tokyo (JP); KOHA CO., LTD, Tokyo (JP)

(21) Appl. No.: 14/404,929

(22) PCT Filed: May 27, 2013
(86) PCT No.: PCT/JP2013/064628

§ 371 Date: Dec. 1, 2014

(30) Foreign Application Priority Data
Jun. 1, 2012 (JP) 2012-125979

(51) Int. Cl. H01L 29/20

(52) U.S. Cl. CPC H01L 29/2003

(57) ABSTRACT

Provided is a semiconductor laminate structure including a Ga₂O₃ substrate and a nitride semiconductor layer with high crystal quality on the Ga₂O₃ substrate, and also provided is a semiconductor element including this semiconductor laminate structure. In one embodiment, this semiconductor laminate structure includes a β-Ga₂O₃ substrate including β-Ga₂O₃ crystal and a principal surface inclined from a (−201) surface to a [102] direction nd a nitride semiconductor layer including AlₓGa_{y}In_{z}N (0≦x≦1, 0≦y≦1, 0≦z≦1, x+y+z=1) crystal formed by epitaxial crystal growth on the principal surface of the β-Ga₂O₃ substrate.

### TECHNICAL FIELD

The invention relates to a semiconductor laminate structure and a semiconductor element.

### BACKGROUND ART

Conventionally, optical device substrates having a Ga₂O₃ substrate and a GaN layer grown on the Ga₂O₃ substrate are known (see, e.g., PTL 1). In PTL 1, the GaN layer is grown on the Ga₂O₃ substrate having a (100) plane as a principal surface.

### CITATION LIST

### Patent Literature

[PTL 1]

JP-A-2009-227545

### SUMMARY OF INVENTION

### Technical Problem

For a laminate structure having a Ga₂O₃ substrate and a GaN layer grown thereon, it is important to grow a high-quality GaN crystal on the Ga₂O₃ substrate in order to reduce the leakage current of a device formed on the GaN layer and to improve the reliability of device characteristics.

It is an object of the invention to provide a semiconductor laminate structure that includes a Ga₂O₃ substrate and a nitride semiconductor layer with high crystal quality on the Ga₂O₃ substrate, as well as a semiconductor element including the semiconductor laminate structure.

### Solution to Problem

According to one embodiment of the invention, a semiconductor laminate structure set forth in [1] to [5] below is provided.

[1] A semiconductor laminate structure, comprising:
a substrate comprising a β-Ga₂O₃ crystal having a principal surface inclined from a (−201) plane to a [102] direction; and
a nitride semiconductor layer comprising an AlₓGa_{y}In_{z}N (0≦x≦1, 0≦y≦1, 0≦z≦1, x+y+z=1) crystal formed by epitaxial crystal growth on the principal surface of the substrate.

[2] The semiconductor laminate structure according to [1], wherein the principal surface is a surface inclined at an off-angle of 0.5° to 2.5° to the [102] direction and −1.0° to 1.0° to a direction from the (−201) plane.

[3] The semiconductor laminate structure according to [2], wherein the principal surface is a surface inclined at an off-angle of 1.0° to 2.0° to the [102] direction and −0.5° to 0.5° to the [010] direction from the (−201) plane.

[4] The semiconductor laminate structure according to any one of [1] to [3], comprising a buffer layer comprising an AlₓGa_{y}In_{z}N (0≦x≦1, 0≦y≦1, 0≦z≦1, x+y+z=1) crystal between the substrate and the nitride semiconductor layer.

[5] The semiconductor laminate structure according to any one of [1] to [3], wherein the nitride semiconductor layer comprises a GaN crystal.

Also, according to another embodiment of the invention, a semiconductor element set forth in [6] below is provided.

[6] A semiconductor element, comprising the semiconductor laminate structure according to any one of [1] to [3].

### Advantageous Effects of Invention

According to one embodiment of the invention, a semiconductor laminate structure can be provided that includes a Ga₂O₃ substrate and a nitride semiconductor layer with high crystal quality on the Ga₂O₃ substrate, as well as a semiconductor element including the semiconductor laminate structure.

### BRIEF DESCRIPTION OF DRAWINGS

FIG. 1 is a vertical cross-sectional view showing a semiconductor laminate structure in a first embodiment.

FIG. 2 is a conceptual diagram illustrating an orientation relationship between a unit cell of β-Ga₂O₃ crystal and a principal surface of a β-Ga₂O₃ substrate.

FIG. 3A is a surface photograph of an example of a nitride semiconductor layer in the present embodiment.

FIG. 3B is a surface photograph of a nitride semiconductor layer in Comparative Example.

FIG. 4A is a graph showing a relation between the magnitude of off-angle of the principal surface of the β-Ga₂O₃ substrate and a density of pits on a surface of the nitride semiconductor layer.

FIG. 4B is a graph showing a relation between the magnitude of off-angle of the principal surface of the β-Ga₂O₃ substrate and a density of pits on a surface of the nitride semiconductor layer.

FIG. 5 is a vertical cross-sectional view showing an LED element in a second embodiment.

### DESCRIPTION OF EMBODIMENTS

### First Embodiment

(Configuration of Semiconductor Laminate Structure)

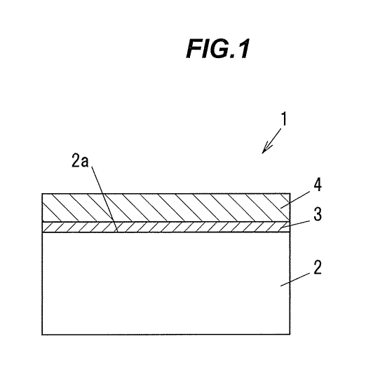

FIG. 1 is a vertical cross-sectional view showing a semiconductor laminate structure 1 in the first embodiment. The semiconductor laminate structure 1 has a β-Ga₂O₃ substrate 2 and a nitride semiconductor layer 4 which is formed on a principal surface 2a of the β-Ga₂O₃ substrate 2 by epitaxial crystal growth. It is preferable to also provide a buffer layer 3 between the β-Ga₂O₃ substrate 2 and the nitride semiconductor layer 4 as shown in FIG. 1 to reduce lattice mismatch between the β-Ga₂O₃ substrate 2 and the nitride semiconductor layer 4.

The β-Ga₂O₃ substrate 2 is formed of a β-Ga₂O₃ crystal. The β-Ga₂O₃ substrate 2 may contain a conductive impurity such as Si. The thickness of the β-Ga₂O₃ substrate 2 is, e.g., 400 μm.

The buffer layer 3 is formed of an AlₓGa_{y}In_{z}N (0≦x≦1, 0≦y≦1, 0≦z≦1, x+y+z=1) crystal. On the β-Ga₂O₃ substrate 2, the buffer layer 3 may be formed in an island pattern or in the form of film. The buffer layer 3 may contain a conductive impurity such as Si.

In addition, among AlₓGa_{y}In_{z}N (0≦x≦1, 0≦y≦1, 0≦z≦1, x+y+z=1) crystals, an AlN crystal (x=1, y=z=0) is particularly preferable to form the buffer layer 3. When the buffer layer 3 is formed of the AlN crystal, adhesion between the β-Ga₂O₃ substrate 2 and the nitride semiconductor layer 4 is further increased. The thickness of the buffer layer 3 is, e.g., 1 to 5 nm.

The buffer layer 3 is formed on the principal surface 2a of the β-Ga₂O₃ substrate 2 by, e.g., epitaxially growing an AlₓGa_{y}In_{z}N (0≦x≦1, 0≦y≦1, 0≦z≦1, x+y+z=1) crystal at a growth temperature of about 370 to 500° C.

The nitride semiconductor layer 4 is formed of an AlₓGa_{y}In_{z}N (0≦x≦1, 0≦y≦1, 0≦z≦1, x+y+z=1) crystal and is particularly preferably formed of a GaN crystal (y=1, x=z=0) from which a high-quality crystal is easily obtained. The thickness of the nitride semiconductor layer 4 is, e.g., 5 μm. The nitride semiconductor layer 4 may contain a conductive impurity such as Si.

The nitride semiconductor layer 4 is formed on the principal surface 2a of the β-Ga₂O₃ substrate 2 via the buffer layer 3 by, e.g., epitaxially growing an AlₓGa_{y}In_{z}N (0≦x≦1, 0≦y≦1, 0≦z≦1, x+y+z=1) crystal at a growth temperature of about 1000° C.

The principal surface 2a of the β-Ga₂O₃ substrate 2 is a surface inclined from a (−201) plane to the [102] direction, i.e., a surface having a normal vector inclined from a normal vector of the (−201) plane to the [102] direction.

Here, the principal surface 2a of the β-Ga₂O₃ substrate 2 is preferably a surface inclined at an off-angle of 0.5° to 2.5° to the [102] direction and −1.0° to 1.0° to the [010] direction from the (−201) plane, i.e., a surface having a normal vector inclined at 0.5° to 2.5° to the [102] direction and −1.0° to 1.0° to the [010] direction from the normal vector of the (−201) plane.

Furthermore, the principal surface 2a of the β-Ga₂O₃ substrate 2 is more preferably a surface inclined at an off-angle of 1.0° to 2.0° to the [102] direction and −0.5° to 0.5° to the [010] direction from the (−201) plane, i.e., a surface having a normal vector inclined 1.0° to 2.0° to the [102] direction and −0.5° to 0.5° to the [010] direction from the normal vector of the (−201) plane.

It is possible to obtain the nitride semiconductor layer 4 with high crystal quality by epitaxially growing an AlₓGa_{y}In_{z}N (0≦x≦1, 0≦y≦1, 0≦z≦1, x+y+z=1) crystal on the principal surface 2a of the β-Ga₂O₃ substrate 2 which is a surface inclined from the (−201) plane as described above.

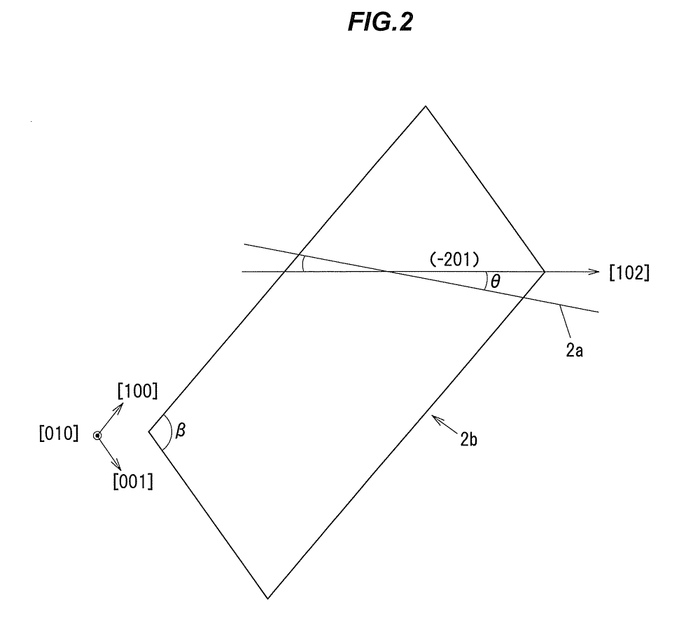

FIG. 2 is a conceptual diagram illustrating an orientation relationship between a unit cell of β-Ga₂O₃ crystal and the principal surface 2a of the β-Ga₂O₃ substrate 2. θ in FIG. 2 indicates an off-angle from the (−201) plane to the [102] direction. The off-angle from the (−201) plane to the [010] direction is defined as 0° in FIG. 2.

A unit cell 2b in FIG. 2 is a unit cell of the β-Ga₂O₃ crystal. The β-Ga₂O₃ crystal has a β-gallia structure belonging to the monoclinic system and typical lattice constants of the β-Ga₂O₃ crystal not containing impurities are a₀=12.23 Å, b₀=3.04 Å, c₀=5.80 Å, α=γ=90° and β=103.7°. Here, a₀, b₀ and c₀ respectively indicate an axis length in the [100] direction, that in the [010] direction and that in the [001] direction.

Off-direction and off-angle of the β-Ga₂O₃ substrate which improve crystal quality of a nitride semiconductor layer in case of forming the nitride semiconductor layer on the β-Ga₂O₃ substrate having a (−201) plane as a principal surface are not known so far.

When a nitride semiconductor layer is formed on the (−201) plane with no off-angle, an off-angle of the nitride semiconductor layer becomes large, a remarkable wavy morphology (step bunching) appears on the surface and the density of generated pits on the surface of the crystal (pores generated on the surface) increases. As a result, leakage current in a structure formed on the nitride semiconductor, e.g., a light-emitting device structure having a p-n junction, increases and this results in a decrease in reliability.

The present inventors discovered that a difference in an off-angle from the (−201) plane between the β-Ga₂O₃ substrate having the (−201) plane as a principal surface and the AlₓGa_{y}In_{z}N (0≦x≦1, 0≦y≦1, 0≦z≦1, x+y+z=1) crystal grown on the principal surface is about 1.5° to the [102] direction and about 0° to the [010] direction. Then, it was found that this difference in the off-angle is a cause of low crystal quality of the nitride semiconductor layer and it is possible to improve the crystal quality of the nitride semiconductor layer by adjusting the principal surface of the β-Ga₂O₃ substrate to have an off-angle corresponding to the off-angle difference.

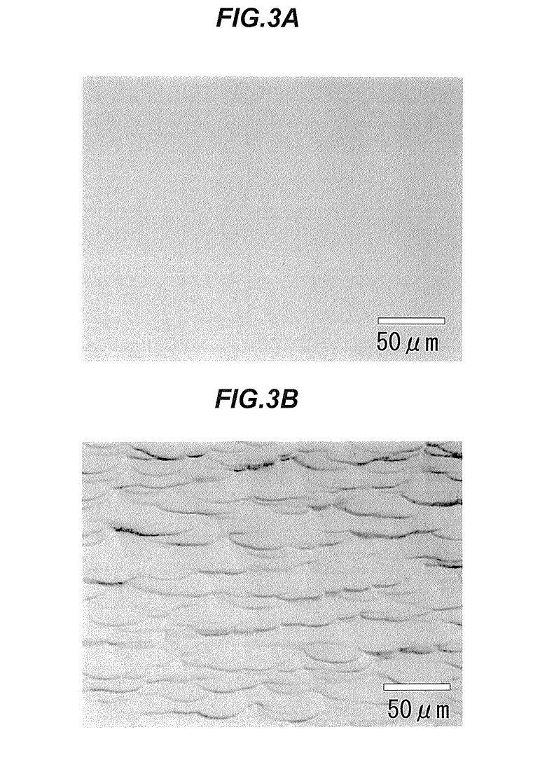

FIG. 3A is a surface photograph of an example of the nitride semiconductor layer 4 in the present embodiment. FIG. 3B is a surface photograph of a nitride semiconductor layer in Comparative Example.

The nitride semiconductor layer 4 shown in FIG. 3A is formed of a Si-doped GaN crystal having a thickness of 6 μm and is obtained by growing an AlN crystal on the β-Ga₂O₃ substrate 2 having a surface inclined at an off-angle of 1.5° to the [102] direction and 0° to the [010] direction from the (−201) plane as the principal surface 2a at a growth temperature of 450° C. to form the buffer layer 3, and then growing a Si-doped GaN crystal thereon at a growth temperature of 1050° C.

The nitride semiconductor layer shown in FIG. 3B is formed of a Si-doped GaN crystal having a thickness of 6 μm and is obtained by growing an AlN crystal on a β-Ga₂O₃ substrate having the (−201) plane with no off-angle as a principal surface at a growth temperature of 450° C. to form a buffer layer, and then growing a Si-doped GaN crystal thereon at a growth temperature of 1050° C.

Although a difference in manufacturing conditions between the nitride semiconductor layer 4 shown in FIG. 3A and the nitride semiconductor layer shown in FIG. 3B is only that the principal surface of the β-Ga₂O₃ substrate has an off-angle or not, step bunching is not observed on surface morphology of the nitride semiconductor layer 4 of FIG. 3A whereas step bunching is observed on surface morphology of the nitride semiconductor layer of FIG. 3B. In addition, the density of pits is 1.25/cm² on the surface of the nitride semiconductor layer 4 of FIG. 3A and is 420/cm² on the surface of the nitride semiconductor layer of FIG. 3B.

These results show that the nitride semiconductor layer 4 in the present embodiment shown in FIG. 3A has higher crystal quality than the nitride semiconductor layer in Comparative Example shown in FIG. 3B.

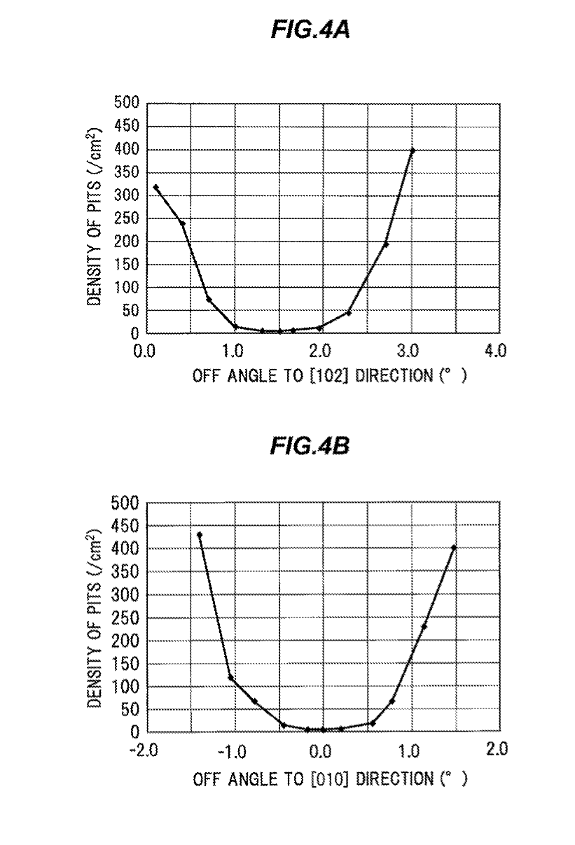

FIGS. 4A and 4B are graphs showing a relation between the magnitude of off-angle of the principal surface 2a of the β-Ga₂O₃ substrate 2 and the density of pits on the surface of the nitride semiconductor layer 4. The horizontal axis indicates the off-angle from the (−201) plane to the [102] direction in FIG. 4A and the off-angle from the (−201) plane to the [010] direction in FIG. 4B. The vertical axis indicates the density of pits on the surface of the nitride semiconductor layer 4 in FIGS. 4A and 4B.

The nitride semiconductor layer 4 used for measurements of FIGS. 4A and 4B is formed of a Si-doped GaN crystal having a thickness of 6 μm and is obtained by growing an AlN crystal on the β-Ga₂O₃ substrate 2 at a growth temperature of 450° C. to form the buffer layer 3, and then growing a Si-doped GaN crystal thereon at a growth temperature of 1050° C.

FIG. 4A shows a change in the density of pits on the surface of the nitride semiconductor layer 4 when the off-angle from the (−201) plane to the [010] direction is fixed to 0° and the off-angle to the [102] direction is changed between 0.0° and 4.0°.

As shown in FIG. 4A, the density of pits on the surface of the nitride semiconductor layer 4 is the minimum when the off-angle from the (−201) plane to the [102] direction is 1.5°.

FIG. 4A shows that the density of pits is particularly small when the off-angle from the (−201) plane to the [102] direction is 1.5°±0.5°, i.e., from 1.0° to 2.0°. It is also shown that the density of pits is about half or less than the case of having no off-angle (0°) when the off-angle from the (−201) plane to the [102] direction is 1.5°±1.0°, i.e., from 0.5° to 2.5°.

Here, given that the semiconductor laminate structure 1 is used for manufacturing, e.g., an LED chip, the density of pits on the nitride semiconductor layer 4 is not more than about 200/cm² when the off-angle from the (−201) plane to the [102] direction is from 0.5° to 2.5° and it is thus possible to manufacture small LED chips of about 300 μm square with a practical yield. Furthermore, the density of pits on the nitride semiconductor layer 4 is not more than about 20/cm² when the off-angle from the (−201) plane to the [102] direction is from 1.0° to 2.0° and it is thus possible to manufacture large LED chips of about 1 mm square with a practical yield. The reason why the allowable density of pits is smaller for larger LED chips is that, even if the density of pits in a state of wafer is the same, chips cut into the large size have a high probability of containing more pits.

FIG. 4B shows a change in the density of pits on the surface of the nitride semiconductor layer 4 when the off-angle from the (−201) plane to the [102] direction is fixed to 1.5° and the off-angle to the [010] direction is changed between −2.0° and 2.0°.

As shown in FIG. 4B, the density of pits on the surface of the nitride semiconductor layer 4 is the minimum when the off-angle from the (−201) plane to the [010] direction is 0.0°.

FIG. 4B shows that the density of pits is small when the off-angle from the (−201) plane to the [010] direction is 0.0°±1.0°, i.e., from −1.0° to 1.0°, and the density of pits is particularly small when the off-angle from the (—201) plane to the [010] direction is 0.0°±0.5°, i.e., from −0.5° to 0.5°.

It is understood from FIGS. 4A and 4B that the principal surface 2a of the β-Ga₂O₃ substrate 2 is preferably a surface inclined at an off-angle of 0.5° to 2.5° to the [102] direction and −1.0° to 1.0° to the [010] direction from the (−201) plane, and more preferably a surface inclined at an off-angle of 1.0° to 2.0° to the [102] direction and −0.5° to 0.5° to the [010] direction from the (−201) plane in order to obtain the nitride semiconductor layer 4 with high crystal quality. In addition, the same results as shown in FIGS. 4A and 4B are obtained also when the nitride semiconductor layer 4 is formed of an AlₓGa_{y}In_{z}N (0≦x≦1, 0≦y≦1, 0≦z≦1, x+y+z=1) crystal other than the GaN crystal.

### Second Embodiment

(Configuration of Semiconductor Element)

The second embodiment is an embodiment of a semiconductor element including the semiconductor laminate structure 1 in the first embodiment. An LED element will be described below as an example of the semiconductor element.

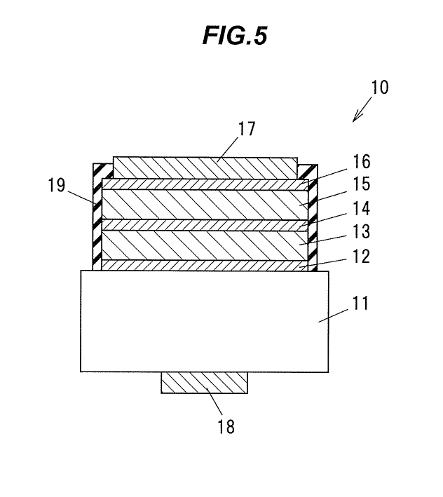

FIG. 5 is a vertical cross-sectional view showing an LED element 10 in the second embodiment. The LED element 10 has β-Ga₂O₃ substrate 11, a buffer layer 12 on the β-Ga₂O₃ substrate 11, an n-type cladding layer 13 on the buffer layer 12, a light-emitting layer 14 on the n-type cladding layer 13, a p-type cladding layer 15 on the light-emitting layer 14, a contact layer 16 on the p-type cladding layer 15, a p-type electrode 17 on the contact layer 16 and an n-type electrode 18 on a surface of the β-Ga₂O₃ substrate 11 opposite to the buffer layer 12.

Then, side surfaces of the laminate composed of the buffer layer 12, the n-type cladding layer 13, the light-emitting layer 14, the p-type cladding layer 15 and the contact layer 16 are covered with an insulating film 19.

Here, the β-Ga₂O₃ substrate 11, the buffer layer 12 and the n-type cladding layer 13 respectively correspond to the β-Ga₂O₃ substrate 2, the buffer layer 3 and the nitride semiconductor layer 4 which constitute the semiconductor laminate structure 1 in the first embodiment. The thicknesses of the β-Ga₂O₃ substrate 11, the buffer layer 12 and the n-type cladding layer 13 are respectively, e.g., 400 μm, 5 nm and 5 μm.

The light-emitting layer 14 is composed of, e.g., three layers of multi-quantum-well structures and a 10 nm-thick GaN crystal film thereon. Each multi-quantum-well structure is composed of an 8 nm-thick GaN crystal film and a 2 nm-thick InGaN crystal film. The light-emitting layer 14 is formed by, e.g., epitaxially growing each crystal film on the n-type cladding layer 13 at a growth temperature of 750° C.

The p-type cladding layer 15 is, e.g., a 150 nm-thick GaN crystal film containing Mg at a concentration of 5.0×10¹⁹/cm³. The p-type cladding layer 15 is formed by, e.g., epitaxially growing a Mg-containing GaN crystal on the light-emitting layer 14 at a growth temperature of 1000° C.

The contact layer 16 is, e.g., a 10 nm-thick GaN crystal film containing Mg at a concentration of 1.5×10²⁰/cm³. The contact layer 16 is formed by, e.g., epitaxially growing a Mg-containing GaN crystal on the p-type cladding layer 15 at a growth temperature of 1000° C.

For forming the buffer layer 12, the n-type cladding layer 13, the light-emitting layer 14, the p-type cladding layer 15 and the contact layer 16, it is possible to use TMG (trimethylgallium) gas as a Ga raw material, TMI (trimethylindium) gas as an In raw material, (C₂H₅)₂SiH₂ (diethylsilane) gas as a Si raw material, Cp₂Mg (bis(cyclopentadienyl)magnesium) gas as a Mg raw material and NH₃ (ammonia) gas as an N raw material.

The insulating film 19 is formed of an insulating material such as SiO₂ and is formed by, e.g., sputtering.

The p-type electrode 17 and the n-type electrode 18 are electrodes in ohmic contact respectively with the contact layer 16 and the β-Ga₂O₃ substrate 11 and are formed using, e.g., a vapor deposition apparatus.

The buffer layer 12, the n-type cladding layer 13, the light-emitting layer 14, the p-type cladding layer 15, the contact layer 16, the p-type electrode 17 and the n-type electrode 18 are formed on the β-Ga₂O₃ substrate 11 in the form of wafer and are then cut into chips of, e.g., 300 μm square in size by dicing, thereby obtaining the LED elements 10.

The LED element 10 is, e.g., an LED chip configured to extract light on the β-Ga₂O₃ substrate 11 side and is mounted on a CAN type stem using Ag paste.

Characteristics of the LED element 10 in the present embodiment will be described below referring to the results of experiments in which an LED element having the (−201) plane with no off-angle as a principal surface was used as Comparative Example.

Firstly, the LED element 10 and the LED element in Comparative Example were respectively mounted on CAN-type stems using Ag paste. Then, current values (a magnitude of leakage current) when applying 2.0V of forward voltage between electrodes were measured.

As a result, the current value of the LED element 10 was 0.08 μA whereas the current value of the LED element in Comparative Example was 10.20 μA. It was confirmed from this result that occurrence of leakage current is suppressed in the LED element 10.

Next, 100 mA of forward current was applied to the LED element 10 and to the LED element in Comparative Example and reliability thereof was evaluated by investigating variation in output of light.

As a result, in the LED element 10, relative output of light after 1000 hours with respect to the initial state was 102.3% and almost no change was observed. On the other hand, the LED element in Comparative Example went off after about 18 hours.

It is considered that these evaluation results were obtained since the crystal quality of the n-type cladding layer 13 of the LED element 10 is higher than that of the n-type cladding layer of the LED element in Comparative Example.

The n-type cladding layer 13 of the LED element 10 is formed on the β-Ga₂O₃ substrate 11 having a surface inclined at a specific off-angle as a principal surface and thus has excellent crystal quality as shown in the first embodiment. In addition, the light-emitting layer 14, the p-type cladding layer 15 and the contact layer 16, which are formed by epitaxial crystal growth on the n-type cladding layer 13 having excellent crystal quality, also have excellent crystal quality. Therefore, the LED element 10 is excellent in leakage current characteristics and reliability.

### Effects of the Embodiment

According to the first and second embodiments, it is possible to obtain a nitride semiconductor layer with high crystal quality by epitaxially growing an AlₓGa_{y}In_{z}N (0≦x≦1, 0≦y≦1, 0≦z≦1, x+y+z=1) crystal on a β-Ga₂O₃ substrate of which principal surface is a surface inclined from the (−201) plane. In detail, for example, step bunching on the nitride semiconductor layer is suppressed and the density of pits on the surface is significantly reduced.

In addition, use of the high-crystal-quality nitride semiconductor layer allows a semiconductor element excellent in leakage current characteristics and reliability to be formed.

It should be noted that the invention is not intended to be limited to the above-mentioned embodiments, and the various kinds of modifications can be implemented without departing from the gist of the invention. For example, although, in the second embodiment, an LED element has been described as an example of a semiconductor element including the semiconductor laminate structure of the first embodiment, the semiconductor element is not limited thereto and may be other elements such as transistor.

In addition, the invention according to claims is not to be limited to the above-mentioned embodiments. Further, it should be noted that all combinations of the features described in the embodiments are not necessary to solve the problem of the invention.

### INDUSTRIAL APPLICABILITY

A semiconductor laminate structure having a Ga₂O₃ substrate and a nitride semiconductor layer with high crystal quality on the Ga₂O₃ substrate and a semiconductor element including the semiconductor laminate structure are provided.

### REFERENCE SIGNS LIST

1 semiconductor laminate structure
2 β-Ga₂O₃ substrate
3 buffer layer
4 nitride semiconductor layer
10 LED element

1. A semiconductor laminate structure, comprising:
a substrate comprising a β-Ga₂O₃crystal having a principal surface inclined from a (−201) place to a [102] direction; and
a nitride semiconductor layer comprising an AlₓGa_{y}In_{z}N (0≦x≦1, 0≦y≦1, 0≦z≦1, x+y+z=1) crystal formed by an epitaxial crystal growth on the principal surface of the substrate.

2. The semiconductor laminate structure according to claim 1, wherein the principal surface comprises a surface inclined at an off-angle of 0.5° to 2.5° to the [102] direction and −1.0° to 1.0° to a [010] direction from the (−201) plane.

3. The semiconductor laminate structure according to claim 2, wherein the principal surface comprises a surface inclined at an off-angle of 1.0° to 2.0° to the [102] direction and −0.5° to 0.5° to the [010] direction from the (−201) plane.

4. The semiconductor laminate structure according to claim 1, further comprising a buffer layer comprising an AlₓGa_{y}In_{z}N (0≦x≦1, 0≦y≦1, 0≦z≦1, x+y+z=1) crystal between the substrate and the nitride semiconductor layer.

5. The semiconductor laminate structure according to claim 1, wherein the nitride semiconductor layer comprises a GaN crystal.

6. A semiconductor element, comprising the semiconductor laminate structure according to claim 1.

7. The semiconductor laminate structure according to claim 2, further comprising a buffer layer comprising an AlₓGa_{y}In_{z}N (0≦x≦1, 0≦y≦1, 0≦z≦1, x+y+z=1) crystal between the substrate and the nitride semiconductor layer.

8. The semiconductor laminate structure according to claim 3, further comprising a buffer layer comprising an AlₓGa_{y}In_{z}N (0≦x≦1, 0≦y≦1, 0≦z≦1, x+y+z=1) crystal between the substrate and the nitride semiconductor layer.

9. The semiconductor laminate structure according to claim 2, wherein the nitride semiconductor layer comprises a GaN crystal.

10. The semiconductor laminate structure according to claim 3, wherein the nitride semiconductor layer comprises a GaN crystal.

11. A semiconductor element, comprising the semiconductor laminate structure according to claim 2.

12. A semiconductor element, comprising the semiconductor laminate structure according to claim 3.

13. The semiconductor laminate structure according to claim 4, wherein the nitride semiconductor layer comprises a GaN crystal.

14. The semiconductor laminate structure according to claim 7, wherein the nitride semiconductor layer comprises a GaN crystal.

15. The semiconductor laminate structure according to claim 8, wherein the nitride semiconductor layer comprises a GaN crystal.

16. A semiconductor element, comprising the semiconductor laminate structure according to claim 13.

17. A semiconductor element, comprising the semiconductor laminate structure according to claim 14.

18. A semiconductor element, comprising the semiconductor laminate structure according to claim 5.

19. A semiconductor element, comprising the semiconductor laminate structure according to claim 9.

20. A semiconductor element, comprising the semiconductor laminate structure according to claim 10.
